(19) United States
(12) Patent Application Publication
(10) Pub. No.: US 2025/0031399 A1
(43) Pub. Date: Jan. 23, 2025

(54) BARRIER LAYERS IN SEMICONDUCTOR DEVICES

(71) Applicant: Taiwan Semiconductor Manufacturing Company, Ltd., Hsinchu (TW)

(72) Inventors: Mu-Min Hung, Hsinchu City (TW); Fan Hsuan Chien, Tainan City (TW); Jyh-Nan Lin, Hsinchu City (TW); Kai-Shiung Hsu, Hsinchu City (TW); Tzu-Chien Cheng, Bade City (TW); Su-Yu Yeh, Tainan City (TW)

(73) Assignee: Taiwan Semiconductor Manufacturing Company, Ltd., Hsinchu (TW)

(21) Appl. No.: 18/353,976

(22) Filed: Jul. 18, 2023

(51) Int. Cl. H01L 29/66; H01L 21/8238; H01L 27/092; H01L 29/06; H01L 29/423; H01L 29/775; H01L 29/78; H01L 29/786

(52) U.S. Cl. CPC H01L 29/66795; H01L 21/823814; H01L 21/823821; H01L 27/0924; H01L 29/0673; H01L 29/42392; H01L 29/66439; H01L 29/775; H01L 29/7851; H01L 29/78696

(57) ABSTRACT

A semiconductor device with a barrier layer between a gate structure and gate spacer layers, and a method of fabricating the same are disclosed. The a method includes forming a fin structure on a substrate, forming a polysilicon structure on the fin structure, performing a nitridation operation to form a barrier layer on the polysilicon structure and the fin structure, forming gate spacer layers on the barrier layer, forming a source/drain region in the fin structure and adjacent to the barrier layer, annealing the gate spacer layers, and replacing the polysilicon structure with a gate structure.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around field effect transistors (GAA FETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1A illustrates an isometric view of a semiconductor device, in accordance with some embodiments.

FIGS. 1B-1G illustrate different cross-sectional views of a semiconductor device with a barrier layer adjacent to a gate structure, in accordance with some embodiments.

FIG. 2 is a flow diagram of a method for fabricating a semiconductor device with a barrier layer, in accordance with some embodiments.

FIGS. 3-5, 6A-13B, 14-17, 18A-18B illustrate isometric views and cross-sectional views of a semiconductor device with a barrier layer at various stages of its fabrication process, in accordance with some embodiments.

FIG. 19 is a flow diagram of a method for fabricating another semiconductor device with a barrier layer, in accordance with some embodiments.

FIGS. 20-24 illustrate cross-sectional views of another semiconductor device with a barrier layer at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., +1%, +2%, +3%, +4%, +5% of the value). These values are merely examples and are not intended to be limiting. The terms “about” and “substantially” can refer to a percentage of the values as interpreted by those skilled in relevant art(s) in light of the teachings herein.

The fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

The GAA transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

Gate spacers formed on the fin structures provide electrical isolation between a gate structure and source/drain (S/D) regions of a finFET. A gate spacer can include one or more gate spacer layers of insulating materials. Due to the increasing demand of scaling down the dimensions of semiconductor devices, thickness of the gate spacer is reduced, requiring higher quality of the gate spacer layers to provide effective isolation between the gate structures and the S/D regions. Thermal treatment, such as annealing process can densify gate spacer layers and improve their isolation performance.

However, annealing at elevated temperatures can promote diffusion of atoms of the S/D regions (for example, germanium (Ge) atoms) into adjacent gate spacer layers. The diffused atoms in the gate spacer layers may be removed during the process of forming the gate structure, thus introducing defects in the gate spacer layers. These defects can create current leakage paths between the gate structure and the S/D regions through the gate spacer layers, thus degrading the isolation performance of the gate spacer layers between the S/D regions and the gate structure.

To address the abovementioned challenges, the present disclosure provides example barrier layer between the gate structure and the gate spacer layers. In some embodiments, the barrier layer can include a nitride layer formed on a polysilicon structure (which is later replaced by the gate structure). In some embodiments, the barrier layer can include a hydrogen-free silicon nitride (SiN) layer, which has high barrier resistance against diffusion of atoms from the S/D regions. The barrier layer can prevent atoms diffusing into the gate spacer layers from diffusing through the barrier layer during the annealing process, and can prevent atoms diffusing into the gate spacer layers from being removed during the process of forming the gate structure. Thus, the presence of the barrier layer can improve the isolation performance of the gate spacer between the S/D regions and the gate structure.

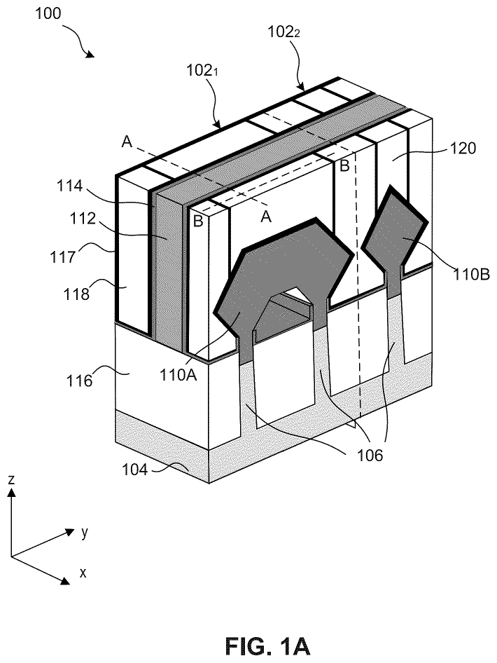

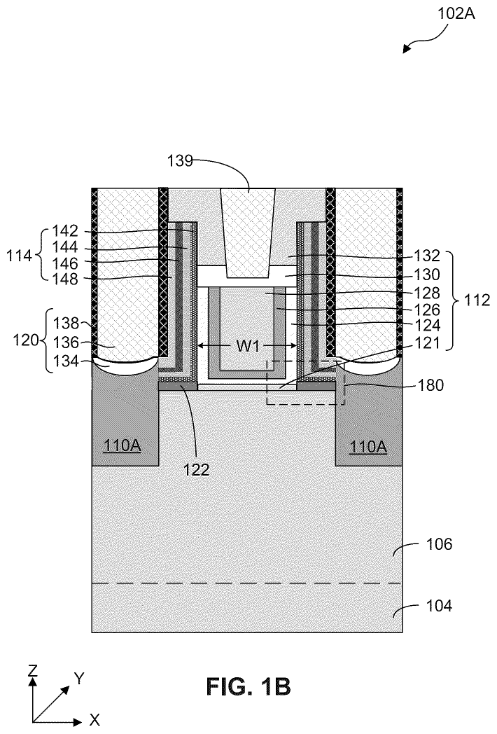

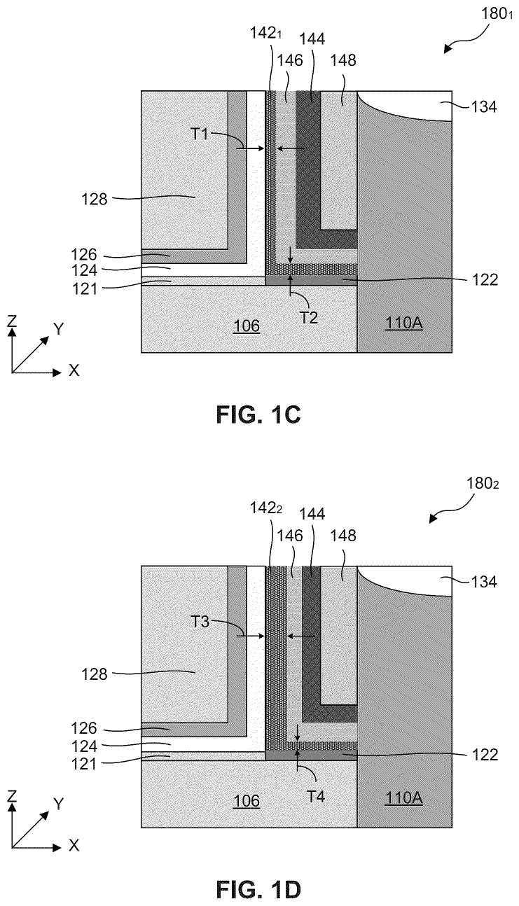

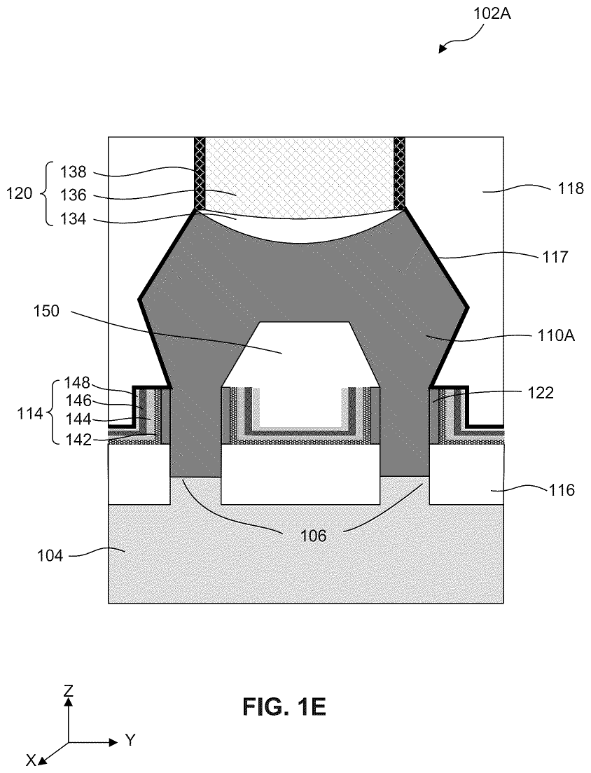

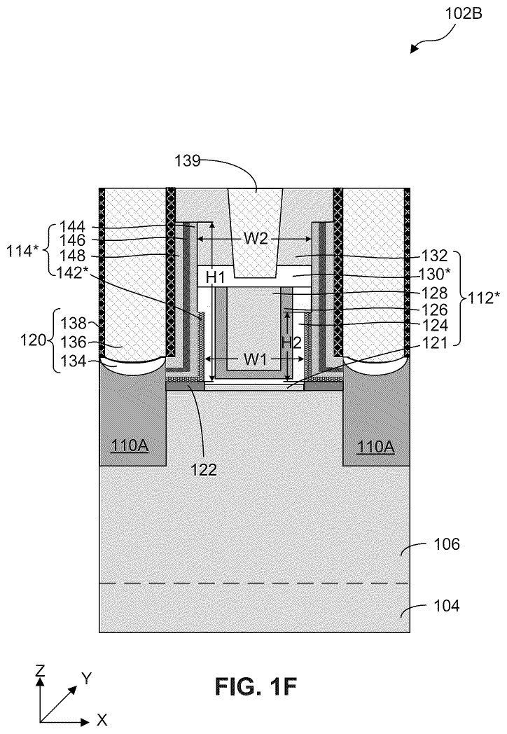

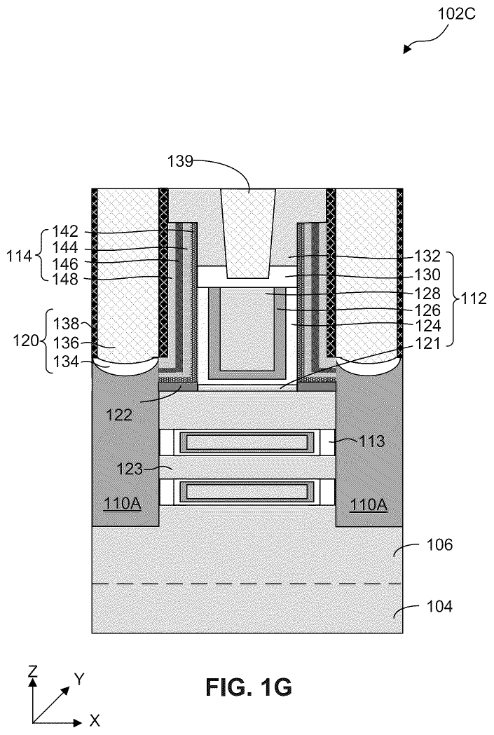

FIG. 1A illustrates an isometric view of a semiconductor device 100 including one or more FETs 102 (e. g., FET 102₁ and FET 102₂), according to some embodiments. FIGS. 1B-1D, IF, and 1G illustrate different cross-sectional views of FET 102 along line A-A of FIG. 1A, according to some embodiments. FIGS. 1C and 1D illustrate different enlarged views of a portion 180 in FIG. 1B, according to some embodiments. FIG. 1E illustrates a cross-sectional view of FET 102 along line B-B of FIG. 1A, according to some embodiments. FIGS. 1B-1G illustrate cross-sectional views of semiconductor device 100 with additional structures that are not shown in FIG. 1A for simplicity. The discussion of elements with the same annotations applies to each other, unless mentioned otherwise. In some embodiments, FET 102 can represent an n-type finFET (“NFET 102”) or a p-type finFET 102 (“PFET 102”) and the discussion of FET 102 applies to both NFET 102 and PFET 102, unless mentioned otherwise. In some embodiments, FET 102 can represent a gate-all-around (GAA) transistor, a nano-sheet transistor, a 2D material transistor, a planar transistor, a back-end-of-line (BEOL) transistor, a NAND transistor, a 3D NAND transistor, an NMOS transistor, or a PMOS transistor. In some embodiments, FET 102 can be electrically connected to other devices not shown in FIGS. 1A-1G. For example, FET 102 can be electrically connected to a passive device (such as an inductor, a capacitor, and/or a resistor), an amplifier, a filter, a memory, and/or a combination thereof.

Referring to FIGS. 1A and 1B, in some embodiments, FET 102 can be a finFET such as FET 102A in FIG. 1B. In some embodiments, FET 102A can include (i) a substrate 104, (ii) fin structures 106 disposed on substrate 104, (iii) a gate structure 112 disposed on fin structure 106, (iv) a gate spacer 114 disposed along sidewalls of gate structure 112, (v) S/D regions 110A (also referred to as “merged S/D regions 110A”) and S/D regions 110B disposed in portions of fin structures 106 that are not covered by gate structure 112, (vi) S/D contact structures 120 disposed on S/D regions 110, (vii) a gate contact structure 139 disposed on gate structure 112, and (viii) a thermal oxide layer 122 disposed on fin structure 106 and under gate spacer 114. In some embodiments, fin structure 106, and gate structure 112 are electrically active and can be electrically coupled to power supplies (not shown) through contact structures, such as S/D contact structures 120 and gate contact structure 139. The discussion of S/D regions 110A applies to S/D regions 110B, unless mentioned otherwise.

FET 102A can be formed on substrate 104. There may be other FETs and/or structures (e.g., isolation structures) formed on substrate 104. Substrate 104 can be a semiconductor material, such as silicon (Si), germanium (Ge), silicon germanium (SiGe), a silicon-on-insulator (SOI) structure, and a combination thereof. Further, substrate 104 can be doped with p-type dopants (e.g., boron, indium, aluminum, or gallium) or n-type dopants (e.g., phosphorus or arsenic). In some embodiments, fin structures 106 can include a material similar to substrate 104 and can have elongated sides extending along an X-axis.

FET 102A can further include shallow trench isolation (STI) regions 116, an etch stop layer (ESL) 117, and an interlayer dielectric (ILD) layer 118. ILD layer 118 can be disposed on ESL 117. ESL 117 can be configured to protect gate structures 112 and/or S/D regions 110. In some embodiments, STI regions 116, ESL 117, and ILD layers 118 can include an insulating material, such as silicon oxide (SiO₂), silicon nitride (SiN), silicon carbon nitride (SiCN), silicon oxycarbon nitride (SiOCN), and silicon germanium oxide (SiGeOₓ).

Referring to FIG. 1B, gate structures 112 can be multi-layered structures. In some embodiments, gate structure 112 can include i) an interfacial oxide layer 121 on fin structure 106; ii) a gate oxide layer 124 disposed on interfacial oxide layer 121; iii) a work function metal (WFM) layer 126 disposed on gate oxide layer 124; iv) a gate metal fill layer 128 disposed on WFM layer 126; v) a conductive capping layer 130 disposed on gate oxide layer 124, WFM layer 126, and gate metal fill layer 128; and vi) an insulating capping layer 132 disposed on conductive capping layer 130. In some embodiments, the stack of WFM layer 126 and gate metal fill layer 128 of gate structure 112 can be referred to as a “metal gate stack” of gate structure 112. In some embodiments, gate structure 112 can have a gate length W1.

In some embodiments, interfacial oxide layer 121 can include a thermal oxide layer. That is, interfacial oxide layer 121 is formed by thermally oxidizing the portion of fin structure 106 under gate structure 112. In some embodiments, gate oxide layer 124 can include a non-thermal oxide layer. That is, gate oxide layer 124 is not formed by thermally oxidizing the portion of fin structure 106 under gate structure 112. In some embodiments, gate oxide layer 124 can include a high-k dielectric material, such as hafnium oxide (HfO₂), titanium oxide (TiO₂), hafnium zirconium oxide (HfZrO), tantalum oxide (Ta₂O₃), zirconium oxide (ZrO₂), and zirconium silicate (ZrSiO₂), and can have a thickness of about 0.5 nm to about 4 nm. Within this thickness range of gate oxide layer 124, adequate electrical isolation between gate structure 112 and channel regions in fin structure 106 can be provided to achieve the low threshold voltage without compromising the size and manufacturing cost of FET 102A.

In some embodiments, gate structure 112 can represent an NFET gate structure (NFET gate structure 112) or a PFET gate structure (PFET gate structure 112). In some embodiments, WFM layer 126 of NFET gate structure 112 can include titanium aluminum (TiAl), titanium aluminum carbide (TiAIC), tantalum aluminum (TaAl), tantalum aluminum carbide (TaAIC), Al-doped Ti, Al-doped TiN, Al-doped Ta, Al-doped TaN, other suitable Al-based materials, or a combination thereof. In some embodiments, WFM layer 126 of PFET gate structure 112 can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, tantalum copper (Ta—Cu), and a combination thereof. In some embodiments, gate metal fill layer 128 can include a suitable conductive material, such as tungsten (W), Ti, silver (Ag), ruthenium (Ru), molybdenum (Mo), copper (Cu), cobalt (Co), Al, iridium (Ir), nickel (Ni), metal alloys, and a combination thereof.

Insulating capping layer 132 protect the underlying conductive capping layer 130 from structural and/or compositional degradation during subsequent processing of the semiconductor device. In some embodiments, insulating capping layer 132 can include a nitride material, such as silicon nitride, and can have a thickness of about 5 nm to about 10 nm for adequate protection of the underlying conductive capping layer 130. Conductive capping layer 130 provides conductive an interface between gate contact structure 139 and gate metal fill layer 128 to electrically connect the metal gate stack of gate structure 112 to gate contact structure 139 without forming gate contact structure 139 directly on or within the metal gate stacks. Gate contact structure 139 is not formed directly on or within the metal gate stacks to prevent contamination of the metal gate stacks by any of the processing materials used in the formation of gate contact structure 139. Contamination of the metal gate stack can lead to the degradation of device performance. Thus, with the use of conductive capping layer 130, the metal gate stack can be electrically connected to gate contact structures 139 without compromising the integrity of gate structures 112. In some embodiments, conductive capping layer 130 and gate contact structure 139 can include a metallic material, such as W, Ru, Ir, Mo, other suitable metallic materials, and a combination thereof. In some embodiments, conductive capping layer 130 and gate contact structure 139 can include the same metallic material or can have metallic materials different from each other.

In some embodiments, for NFET 102A, each of S/D regions 110A can include an epitaxially-grown semiconductor material, such as Si, Ge, SiGe, and silicon phosphide (SiP), and n-type dopants, such as phosphorus and other suitable n-type dopants. In some embodiments, for PFET 102A, each of heavily-doped S/D regions 110A can include an epitaxially-grown semiconductor material, such as Si, Ge, SiGe, and SiP, and p-type dopants, such as boron and other suitable p-type dopants. In some embodiments, dopant concentration in S/D regions 110A can be about 10¹⁹ atoms/cm³ to about 10²¹ atoms/cm³.

In some embodiments, S/D contact structures 120 can include silicide layers 134 disposed on S/D regions 110A, contact plugs 136 disposed on silicide layers 134, and nitride barrier layers 138 along sidewalls of contact plugs 136. In some embodiments, silicide layers 134 can include titanium silicide (TiₓSi_{y}), tantalum silicide (TaₓSi), molybdenum silicide (MoₓSi_{y}), nickel silicide (NiₓSi_{y}), cobalt silicide (CoₓSi_{y}), tungsten silicide (WₓSi_{y}), or a combination thereof. In some embodiments, contact plugs 136 can include conductive materials, such as cobalt (Co), tungsten (W), ruthenium (Ru), iridium (Ir), nickel (Ni), osmium (Os), rhodium (Rh), aluminum (Al), molybdenum (Mo), copper (Cu), zirconium (Zr), stannum (Sn), silver (Ag), gold (Au), zinc (Zn), cadmium (Cd), and a combination thereof.

In some embodiments, each gate spacer 114 can include gate spacer layers 144, 146, and 148. In some embodiments, gate spacer layer 148 can be disposed directly on sidewall and bottom surface of nitride barrier layer 138. In some embodiments, gate spacer layer 146 can be disposed directly on sidewall and bottom surface of gate spacer layer 148. In some embodiments, gate spacer layer 144 can be disposed directly on sidewall and bottom surface of gate spacer layer 146. In some embodiments, gate spacer layer 144, gate spacer layer 146, and gate spacer layer 148 can each include a horizontal portion that is in direct contact with S/D regions 110A. In some embodiments, gate spacer layer 144 can include a silicon oxycarbide (SiCO) layer, gate spacer layer 146 can include a silicon carbon oxynitride (SiCON) layer, and gate spacer layer 148 can include a silicon nitride (SiN) layer. In some embodiments, each of gate spacer layers 144, 146, and 148 can have a thickness of about 0.5 nm to about 2 nm.

In some embodiments, gate spacer 114 can further include a barrier layer 142. In some embodiments, barrier layer 142 can include a nitride layer, such as SiN or other suitable dielectric nitrides. In some embodiments, barrier layer 142 can include a hydrogen-free SiN layer. In some embodiments, barrier layer 142 can have an L-shaped cross-sectional profile and can include a vertical portion and a horizontal portion. In some embodiments, the vertical portion can be disposed between a side surface of gate structure 112 and a side surface of gate spacer layer 144. In some embodiments, one side of the vertical portion can be in direct contact with HK gate dielectric layer 124 and the other side of the vertical portion can be in direct contact with gate spacer layer 144. In some embodiments, a sidewall of the vertical portion can be substantially aligned with sidewall of thermal oxide layer 122. The height of the vertical portion along a Z-axis is greater than the heights of the vertical portions of gate spacer layers 144, 146, and 148. In some embodiments, the horizontal portion of barrier layer 142 can be disposed between gate spacer layer 144 and thermal oxide layer 122. In some embodiments, a first side of the horizontal portion can be in direct contact with S/D regions 110A, a second side of the horizontal portion can in direct contact with thermal oxide layer 122, and a third side of the horizontal portion can be in direct contact with gate spacer layer 144. The width of the horizontal portion along an X-axis is greater than the widths of the horizontal portions of gate spacer layers 144, 146, and 148. In some embodiments, a top surface of barrier layer 142 can be substantially coplanar with top surfaces of gate spacer layers 144, 146, and/or 148. In some embodiments, the top surface of barrier layer 142 can be above a top surface of conductive capping layer 130 and below a top surface of insulating capping layer 132. In some embodiments, the top surface of barrier layer 142 can be covered by insulating capping layer 132.

In some embodiments, gate spacer layers 144, 146, and 148 can be densified layers (for example, densified by an annealing process) to improve their isolation performance between gate structure 112 and S/D regions 110A. In some embodiments, during the annealing process, atoms in S/D regions 110A (for example, Ge atoms or Si atoms) can diffuse into gate spacer layers 144, 146, and 148. In the process of forming gate structure 112, such atoms diffusing into gate spacer layers 144, 146, and 148 are subject to being removed, creating defects in gate spacer layers 144, 146, and 148. These detects can create current leakage paths between gate structure 112 and S/D regions 110A, and degrade the isolation performance of gate spacer layers 144, 146, and 148. The barrier layer 142 can resist the diffusion of atoms from S/D regions 110A through gate spacer layers 144, 146, and/or 148. In addition, barrier layer 142 can prevent atoms of S/D regions 110A diffusing into gate spacer layers 144, 146, and/or 148 from being removed by etching chemicals during the process of forming gate structure 112, and consequently preventing the formation of current leakage paths between gate structure 112 and S/D regions. Thus, the presence of barrier layer 142 can prevent damage to gate spacer 114 and improve device performance.

In some embodiments, barrier layer 142 can have a thickness of about 2 Å to about 5 Å. In some embodiments, if the thickness of barrier layer 142 is too thin (e. g., less than about 2 Å), barrier layer 142 may not effectively resist the atoms coming from S/D regions 110A from diffusing through barrier layer 142, and may not effectively prevent these atoms from being removed by etching chemicals during the process of forming gate structure 112, and may not effectively prevent the formation of current leakage paths between gate structure 112 and S/D regions. In some embodiments, if the thickness of barrier layer 142 is too thick (e. g., greater than 5 Å), it may take a long time to form barrier layer 142 and reduce the efficiency of fabricating FET 102A.

In some embodiments, the vertical and horizontal portions of barrier layer 142 can have substantially the same thicknesses (as shown in FIG. 1C) or different thicknesses (as shown in FIG. 1D). FIG. 1C, an enlarged view 1801 of a region 180 in FIG. 1B, shows a barrier layer 1421, which is an example of barrier layer 142 in FIG. 1B. A thickness T1 of the vertical portion of barrier layer 1421 can be substantially the same as a thickness T2 of the horizontal portion of barrier layer 1421. FIG. 1D, another enlarged view 1802 of region 180 in FIG. 1B, shows a barrier layer 1422, which is another example of barrier layer 142 in FIG. 1B. A thickness T3 of the vertical portion of barrier layer 1422 can be greater than a thickness T4 of the horizontal portion of barrier layer 1422. In some embodiments, T3 is greater than T4 by at least 10%. In some embodiments, a ratio between T3 and T4 can be between 1.1 and 3. In some embodiments, with the vertical portion having thickness T3 greater than thickness T4 of the horizontal portion, barrier layer 1422 can adequately resist the atoms coming from S/D regions 110A from diffusing through barrier layer 1422, and can adequately prevent these atoms from being removed by etching chemicals during the process of forming gate structure 112, thus adequately preventing the formation of current leakage paths between gate structure 112 and S/D regions.

Referring to FIG. 1A, in some embodiments, semiconductor device 100 can have more than one FETs 102, such as FETs 102₁ and 102₂ formed on substrate 104, and each can have its own single or multiple fin structure 106. In some embodiments, FETs 102₁ and 102₂ can have common gate structure 112. In some embodiments, each of FETs 102₁ and 102₂ can have its own gate structure 112. In some embodiments, each of FETs 102₁ and 102₂ can have its own S/D regions. For example, FET 102₁ can have S/D region 110A, and FET 102₂ can have S/D region 110B, as shown in FIG. 1A. In some embodiments, FETs 102₁ and 102₂ can have different structure of barrier layer 142 as shown in FIGS. 1B-1D. In some embodiments, FET 102₁ can have barrier layer 142₁, as shown in FIG. 1C, and FETs 102₂ can have barrier layer 142₂, as shown in FIG. 1D. In some embodiments, FET 102₁ can have barrier layer 142₂, as shown in FIG. 1D, and FETs 102₂ can have barrier layer 142₁, as shown in FIG. 1C. In some embodiments, a thickness T3 of the vertical portion of barrier layer 142₂ can be greater than a thickness T1 of the vertical portion of barrier layer 142₁ by at least 10%. In some embodiments, a thickness T4 of the horizontal portion of barrier layer 142₂ can be no less than a thickness T2 of the horizontal portion of barrier layer 142₁.

FIG. 1E illustrates a cross-sectional view of FET 102 along line B-B of FIG. 1A. The discussion of elements in FIGS. 1A-1E with the same annotations applies to each other, unless mentioned otherwise. In some embodiments, merged S/D region 110A can be disposed on two adjacent fin structures 106 and over a portion of STI region 116 between the two adjacent fin structures 106. In some embodiments, a cavity 150 can be enclosed by merged S/D region 110A and the portion of STI region 116 between the two adjacent fin structures 106. In some embodiments, barrier layer 142 can be disposed on STI regions 116 and sidewalls of thermal oxide layer 122. In some embodiments, barrier layer 142 can be disposed in cavity 150 and on the portion of STI region 116 between the two adjacent fin structures 106. In some embodiments, gate spacer layers 144, 146, and 148 can be disposed on barrier layer 142. In some embodiments, gate spacer layers 144, 146, and 148 can be disposed in cavity 150 and on a portion of barrier layer 142 between the two adjacent fin structures 106.

FIG. 1F illustrates a different cross-sectional view of FET 102 along line A-A of FIG. 1A. The discussion of the cross-sectional view of FIGS. 1B, 1C, and 1D applies to FIG. 1F, unless mentioned otherwise. The discussion of elements in FIGS. 1A-IF with the same annotations applies to each other, unless mentioned otherwise. In some embodiments, FET 102 can be a finFET, such as FET 102B in FIG. 1F. In some embodiments, FET 102B can include a gate spacer 114*, which can include gate spacer layers 144, 146, and 148. In some embodiments, gate spacer 114* can further include a barrier layer 142*. The discussion of barrier layer 142 applies to barrier layer 142*, unless mentioned otherwise. In some embodiments, barrier layer 142* can have an L-shaped cross-sectional profile and can include a vertical portion and a horizontal portion. A top surface of the vertical portion is non-coplanar with top surfaces of gate space layers 144, 146, and 148 and is covered by HK gate dielectric layer 124. The height of the vertical portion along a Z-axis is less than the heights of the vertical portions of gate spacer layers 144, 146, and 148. In some embodiments, a ratio between a height H2 of barrier layer 142* and a height H1 of gate space layers 144, 146, and 148 can be about 30% to about 50%. Referring to FIG. 1F, in some embodiments, FET 102B can include a gate structure 112*. The discussion of gate structure 112 of FET 102A in FIG. 1B applies to gate structure 112*, unless mentioned otherwise. In some embodiments, gate structure 112* of FET 102B includes a conductive capping layer 130* having a width W2 greater than a width W1 between a pair of opposite barrier layers 142*, as shown in FIG. 1F. In some embodiments, the reduced height H2 of barrier layer 142* allows conductive capping layer 130* to extend laterally to be in contact with gate spacer layer 144, such that W2 can be greater than W1. In some embodiments, a greater width can reduce the resistance of conductive capping layer 130* compared with conductive capping layer 130, and further improve the performance of gate structure 112*.

Similar to barrier layer 142 in FET 102A in FIG. 1B, barrier layer 142* of FET 102B can improve the isolation performance of gate spacer 114* between gate structure 112* and S/D regions 110A. In some embodiments, the presence of barrier layer 142* can prevent atoms of S/D regions 110A diffusing into gate spacer layers 144, 146, and 148 from diffusing through barrier layer 142*, when gate spacer layers 144, 146, and 148 are being densified. In some embodiments, the presence of barrier layer 142* can prevent atoms of S/D regions 110A diffusing into gate spacer layers 144, 146, and 148 from being removed during the process of forming gate structure 112*, thus preventing the damage to gate spacer 114*.

Referring to FIG. 1A, in some embodiments, FETs 102and 102₂ on the same substrate 104 can have different structures of barrier layers 142 and/or 142* as shown in FIGS. 1B and 1E. In some embodiments, FET 102₁ can have barrier layer 142, as shown in FIG. 1B, and FETs 102₂ can have barrier layer 142*, as shown in FIG. 1F. In some embodiments, FET 102₁ can have barrier layer 142*, as shown in FIG. 1F, and FETs 102₂ can have barrier layer 142, as shown in FIG. 1B. In some embodiments, a height of barrier layer 142 of FET 102₁ can be the same as height H1 of gate spacer layers 144, 146, and 148. In some embodiments, a ratio between height H2 of barrier layer 142* of FET 102₂ and height H1 of barrier layer 142 of FET 102₁ can be about 30% to about 50%.

FIG. 1G illustrates a different cross-sectional view of FET 102 along line A-A of FIG. 1A. The discussion of the cross-sectional view of FIGS. 1B-1F applies to FIG. 1G, unless mentioned otherwise. The discussion of elements in FIGS. 1A-1G with the same annotations applies to each other, unless mentioned otherwise. Referring to FIG. 1G, in some embodiments, FET 102 can be a GAA FET, such as FET 102C instead of a finFET (such as FET 102A shown in FIG. 1B or FET 102B shown in FIG. 1F). For FET 102C, gate structure 112 can have a cross-sectional view as shown in FIG. 1G. Gate structure 112 can be wrapped around nanostructured channel regions 123. As used herein, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm. Nanostructured channel regions 123 can include semiconductor materials similar to or different from substrate 104. In some embodiments, nanostructured channel regions 123 can include Si, SiAs, SiP, SiC, SiCP, SiGe, silicon germanium boron (SiGeB), germanium boron (GeB), silicon germanium stannum boron (SiGeSnB), a III-V semiconductor compound, or other suitable semiconductor materials. Though rectangular cross-sections of nanostructured channel regions 123 are shown, nanostructured channel regions 123 can have cross-sections of other geometric shapes (e.g., circular, elliptical, triangular, or polygonal). Gate portions of gate structure 112 surrounding nanostructured channel regions 123 can be electrically isolated from adjacent S/D regions 110A by inner spacers 113. Inner spacers 113 can include an insulating material, such as SiOₓ, SiN, SiCN, SiOCN, and other suitable insulating materials.

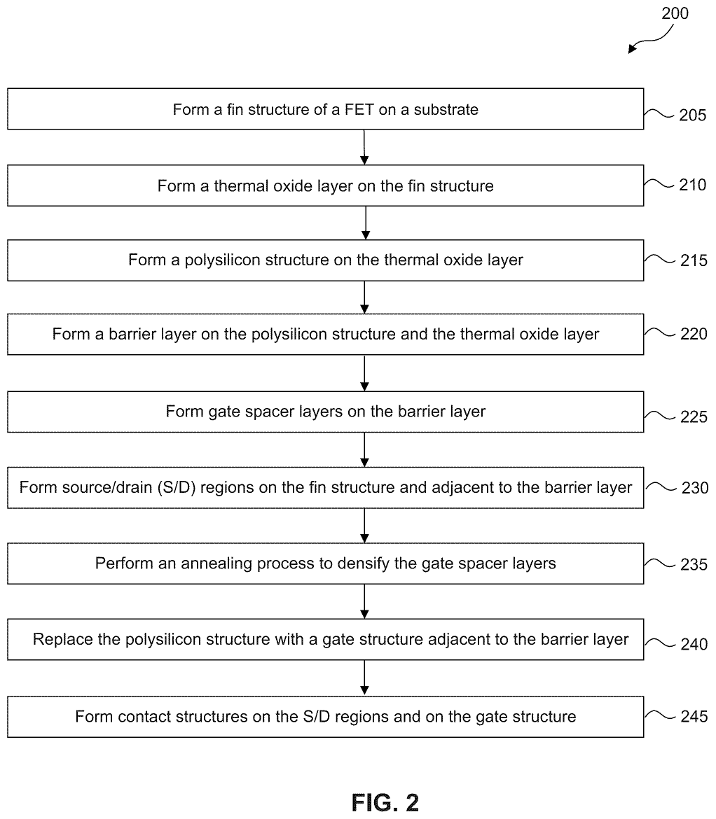

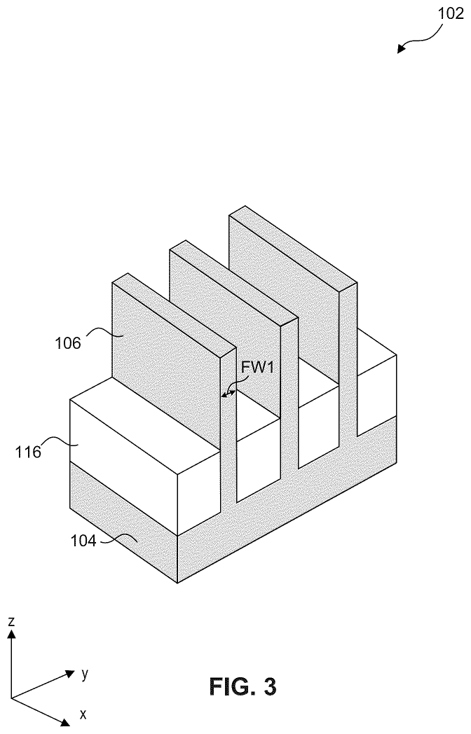

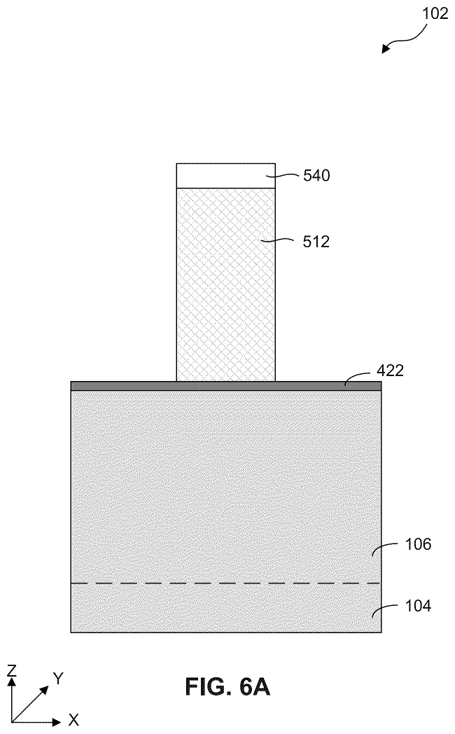

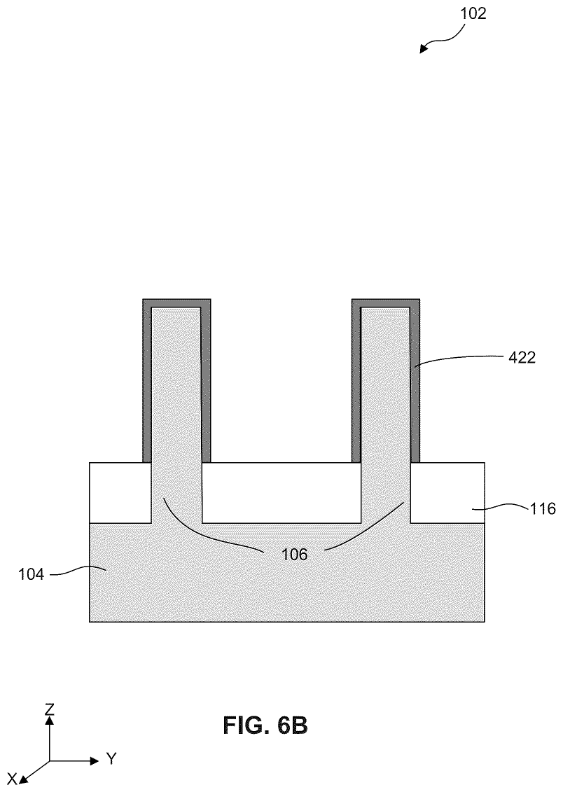

FIG. 2 is a flow diagram of an example method 200 for fabricating FET 102A with the cross-sectional view shown in FIG. 1B, according to some embodiments. For illustrative purposes, the operations illustrated in FIG. 2 will be described with reference to the example fabrication process for fabricating FET 102A as illustrated in FIGS. 3-5, 6A-13B, 14-17, 18A-18B. FIGS. 3-5 are isometric views of FIG. 1A at various stages of fabrication, according to some embodiments. FIGS. 6A, 7A, 8A, 8B, 9A, 10A, 11A, 12A, 13A, 14-17, and 18A are cross-sectional views of FET 102A along line A-A of FIG. 1A at various stages of fabrication, according to some embodiments. FIGS. 6B, 7B, 9B, 10B, 11B, 12B, 13B, and 18B are cross-sectional views of FET 102A along line B-B of FIG. 1A at various stages of fabrication, according to some embodiments. Operations can be performed in a different order or not performed depending on specific applications. It should be noted that method 200 may not produce a complete FET 102A. Accordingly, it is understood that additional processes can be provided before, during, and after method 200, and that some other processes may only be briefly described herein. Elements in FIGS. 3-5, 6A-13B, 14-17, 18A-18B with the same annotations as elements in FIGS. 1A-1E are described above.

In operation 205, a fin structure of a FET is formed on a substrate. For example, as shown in FIG. 3, fin structures 106 of FET 102 are formed on substrate 104. The formation of fin structures 106 can include sequential operations of (i) forming a patterned masking layer (not shown) on substrate 104, and (ii) etching substrate 104 to form structures 106. After the formation of fin structures 106, STI regions 116 can be formed as shown in FIG. 3.

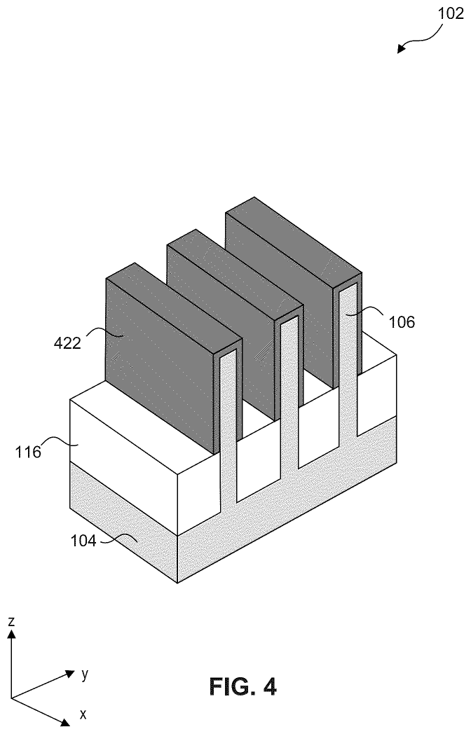

Referring to FIG. 2, in operation 210, a thermal oxide layer is formed on the fin structure. For example, as shown in FIG. 4, a thermal oxide layer 422 is formed on fin structures 106. Thermal oxide layer 422 can be formed in a thermal oxidation process. In some embodiments, the thermal oxidation process can include oxidizing the surfaces of fin structures 106 that are exposed above STI regions 116 in an oxidizing ambient at a temperature of about 30° C. to about 200° C. or at other suitable oxidation temperatures. In some embodiments, the oxidizing ambient can include a combination of ozone (O₃), a mixture of ammonia hydroxide, hydrogen peroxide, and water, and/or a mixture of hydrochloric acid, hydrogen peroxide, and water. In some embodiments, the thermal oxidation process can include oxidizing the surfaces of fin structures 106 that are exposed above STI regions 116 in an oxygen ambient or in a steam and oxygen ambient at a temperature of about 400° C. to about 600° C.

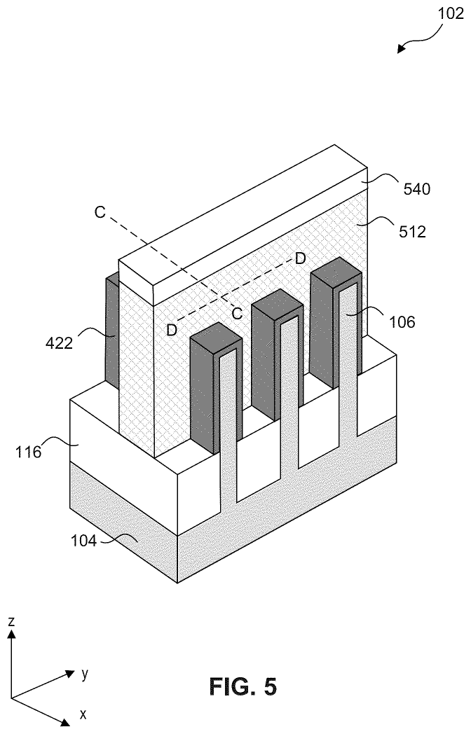

Referring to FIG. 2, in operation 215, a polysilicon structure is formed on the thermal oxide layer. For example, as described with reference to FIGS. 5, 6A, and 6B, a polysilicon structure 512 is formed on thermal oxide layer 422. FIGS. 6A and B are cross-sectional views of FET 102A along line C-C and D-D of FIG. 5, respectively. Polysilicon structure 512 is a sacrificial structure and can be replaced in a subsequent replacement process to form gate structure 112. In some embodiments, hard mask layer 540 can be formed on polysilicon structure 512 to prevent or minimize the etching of polysilicon structure 512 during the formation of gate spacer layers 944, 946, and 948 in subsequent operation 225. In some embodiments, the formation of polysilicon gate structure 512 can include sequential operations of i) blanket depositing a layer of polysilicon material, ii) forming and patterning hard mask layer 540 on the layer of polysilicon material, and iii) etching the layer of polysilicon material through the patterned hard mask layer 540. In some embodiments, the blanket deposition of the layer of polysilicon material can include a chemical vapor deposition (CVD) process, a physical vapor deposition (PVD), an atomic layer deposition (ALD) process, or any other suitable deposition process. In some embodiments, etching of the deposited layer of polysilicon material can include a dry etch, a wet etch, or a combination thereof.

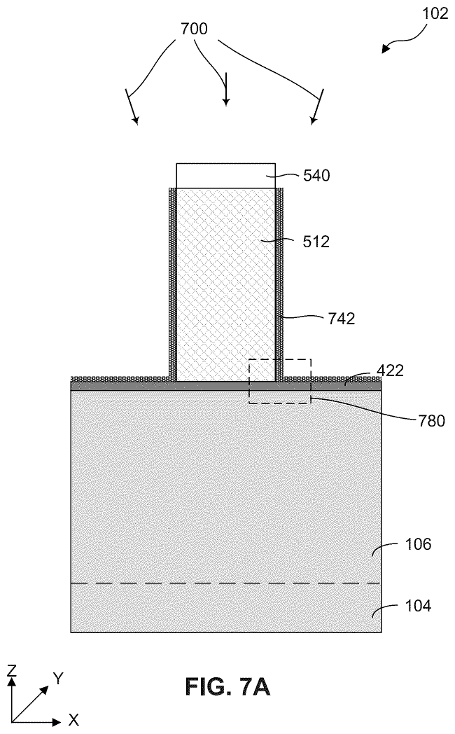

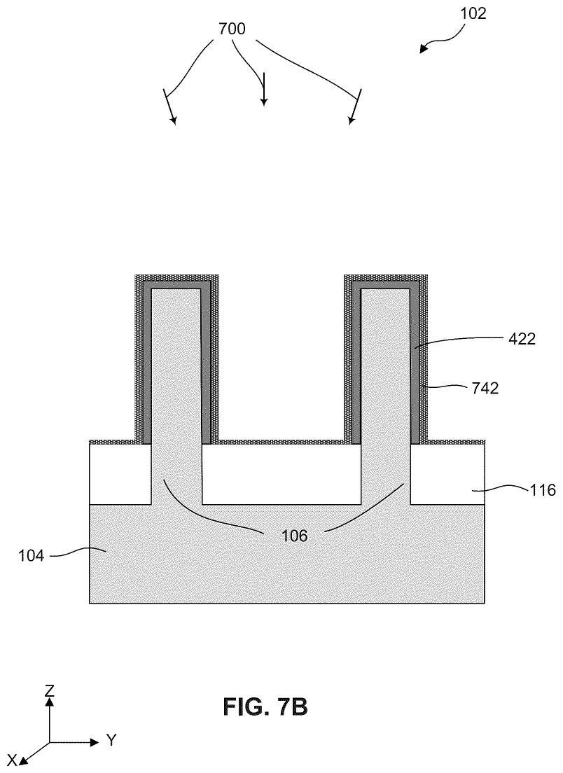

Referring to FIG. 2, in operation 220, a barrier layer is formed on the polysilicon structure and the thermal oxide layer. For example, as described with reference to FIGS. 7A and 7B, a barrier layer 742 is formed on sidewalls of polysilicon structure 512, surfaces of thermal oxide layer 422, and surfaces of STI regions 116. In some embodiments, the formation of barrier layer 742 can include performing a nitridation process on the exposed surfaces of polysilicon structure 512 and thermal oxide layer 422. In some embodiments, the nitridation process can include exposing the uncovered surfaces of polysilicon structure 512, STI regions 116, and thermal oxide layer 422 to a nitrogen plasma 700. In some embodiments, the formation of barrier layer 742 can include performing a nitridation process on the exposed surfaces of polysilicon structure 512, STI regions 116, and thermal oxide layer 422 to form a SiN layer or a hydrogen-free SiN layer on the sidewalls of polysilicon structure 512, the surfaces of thermal oxide layer 422, and the surfaces of STI regions 116. In some embodiments, the formation of barrier layer 742 can include forming hydrogen-free SiN layer with a thickness of about 2 Å to about 5 Å. In some embodiments, the thickness of barrier layer 742 can be controlled by exposing polysilicon structure 512 and thermal oxide layer 422 to nitrogen plasma 700 for a duration of about 1 sec to about 5 sec.

In some embodiments, nitrogen plasma 700 can be generated by ionizing a nitrogen gas inside a processing chamber. In some embodiments, the nitrogen gas used for generating nitrogen plasma 700 can have a purity of about 99.9%. In some embodiments, the purity of the nitrogen gas used for generating nitrogen plasma 700 can be higher than about 99.9%. In some embodiments, a pressure of the nitrogen gas used for generating nitrogen plasma 700 can be between about 0.1 Torr and about 0.8 Torr. In some embodiments, a flow rate of the nitrogen gas used for generating nitrogen plasma 700 can be between about 1 sccm and about 3000 sccm. In some embodiments, a power to generate nitrogen plasma 700 can be between about 600 W and about 800 W. In some embodiments, nitrogen plasma 700 can be generated by ionizing other nitrogen-based gases, such as N₂O, NH₃, and/or a combination thereof.

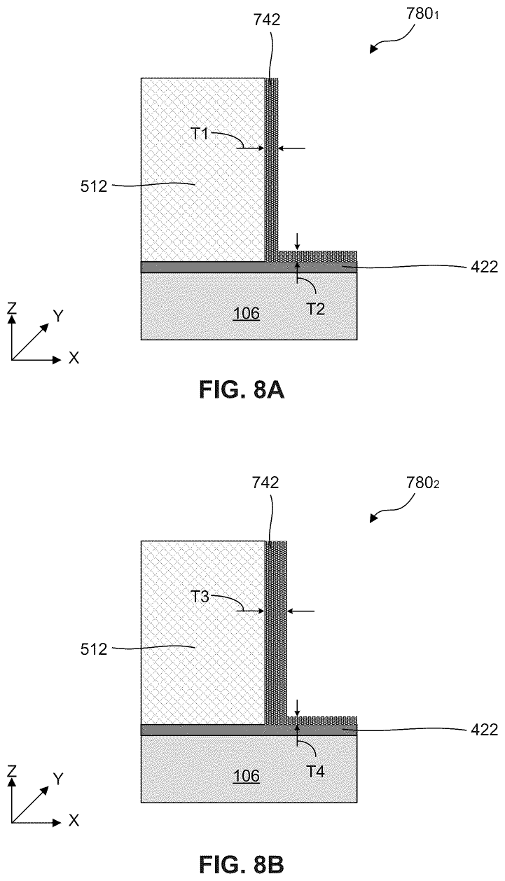

In some embodiments, the formation of barrier layer 742 can include forming a vertical portion of barrier layer 742 on sidewalls of polysilicon structure 512 and forming a horizontal portion of barrier layer 742 on a top surface of thermal oxide layer 422 that is not covered by polysilicon structure 512. In some embodiments, by controlling the pressure of nitrogen plasma 700 and/or by controlling other nitridation parameters, such as the type of the gas to form nitrogen plasma, the flow rate of the gas, the power to generate the plasma, the nitridation duration, etc, the vertical and horizontal portions of barrier layer 742 can be formed with substantially equal thicknesses. For example, as described with reference to FIG. 8A, an enlarged view 7801 of a region 780 in FIG. 7A, the vertical portion of barrier layer 742 can be formed with thickness T1 and the horizontal portion of barrier layer 742 can be formed with thickness T2, which is substantially equal to T1.

In some embodiments, the formation of barrier layer 742 can include forming the vertical and horizontal portions with different thicknesses. In some embodiments, by controlling parameters in the nitridation process, the vertical portion can be controlled to have a thickness greater than that of the horizontal portion. For example, as described with reference to FIG. 8B, another enlarged view 7802 of region 780 in FIG. 7A, the vertical portion of barrier layer 742 can be formed with thickness T3 and the horizontal portion of barrier layer 742 can be formed with thickness T4, with T3 being greater than T4. In some embodiments, by controlling nitridation parameters, barrier layer 742 of FIG. 8B can be formed with a thickness ratio between T3 and T4 being controlled. In some embodiments, the ratio between T3 and T4 can be controlled to be between about 1 and about 3.

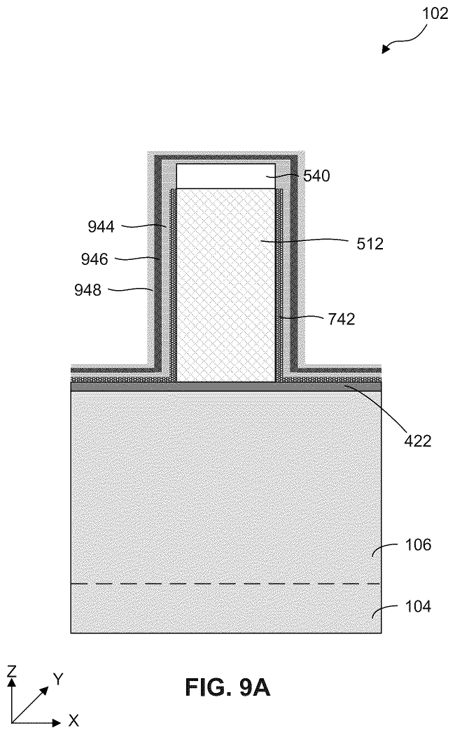

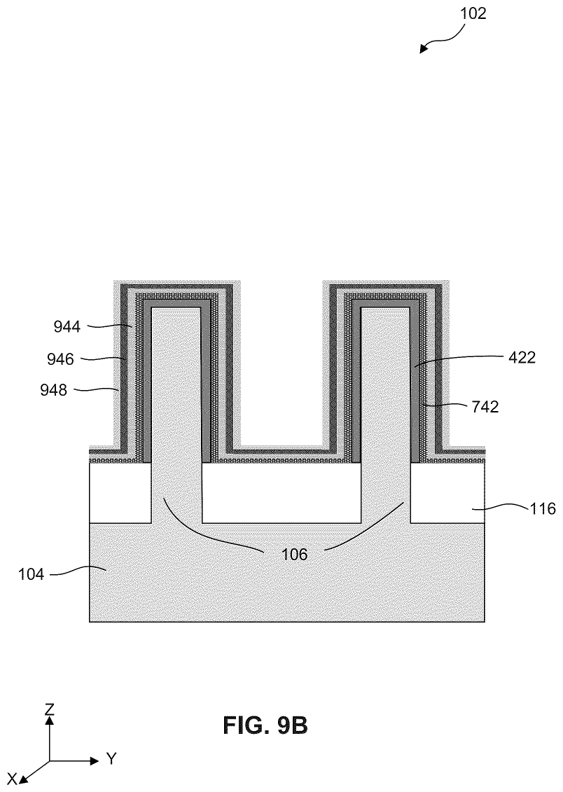

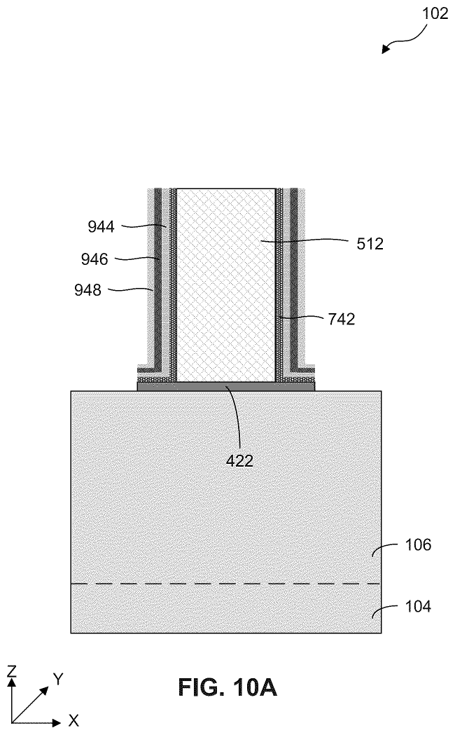

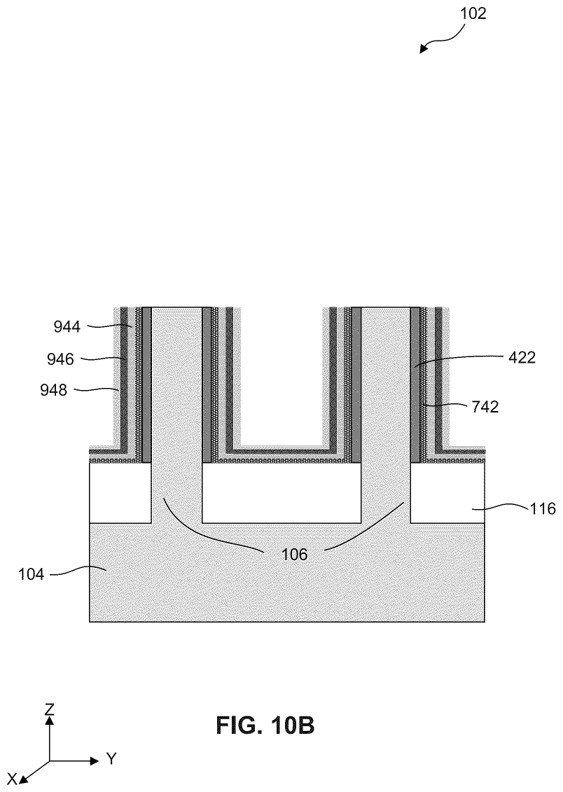

Referring to FIG. 2, in operation 225, gate spacer layers are formed on the barrier layer. For example, as described with reference to FIGS. 9A and 9B, gate spacer layers 944, 946, and 948 are formed on barrier layer 742 and hard mask 540. The formation of gate spacer layers 944, 946, and 948 can include sequentially operation of (i) depositing gate spacer layer 944 on barrier layer 742 and hard mask layer 540, (ii) depositing gate spacer layer 946 on gate spacer layer 944, and (iii) depositing gate spacer layer 948 on gate spacer layer 946. In some embodiments, depositing gate spacer layers 944, 946, and 948 can include depositing the materials of gate spacer layers 944, 946, and 948 in a CVD, PVD, ALD, or any other suitable deposition process. In some embodiments, hard mask 540 and portions of thermal oxide layer 422 can be etched during the etching of the portions of gate spacer layers 944, 946, 948 to form the structure of FIGS. 10A and 10B.

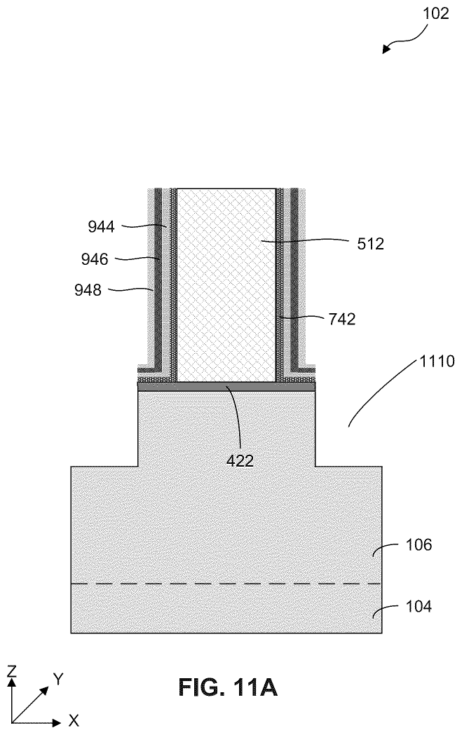

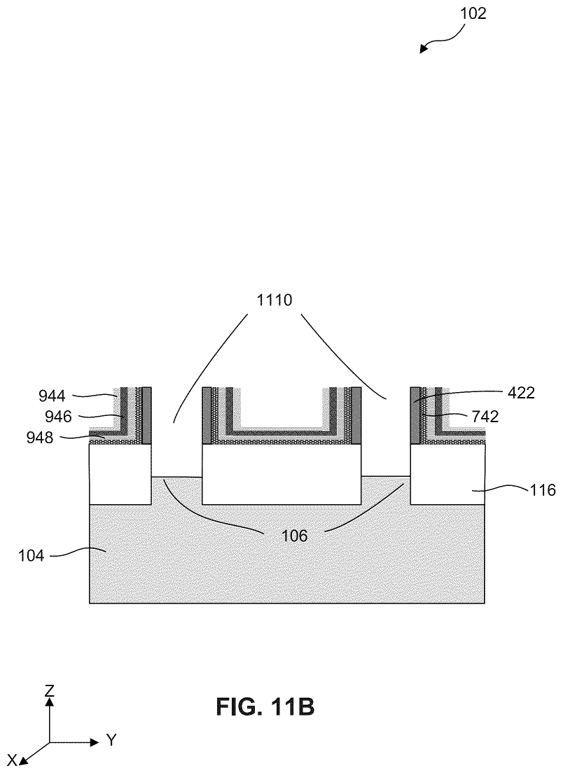

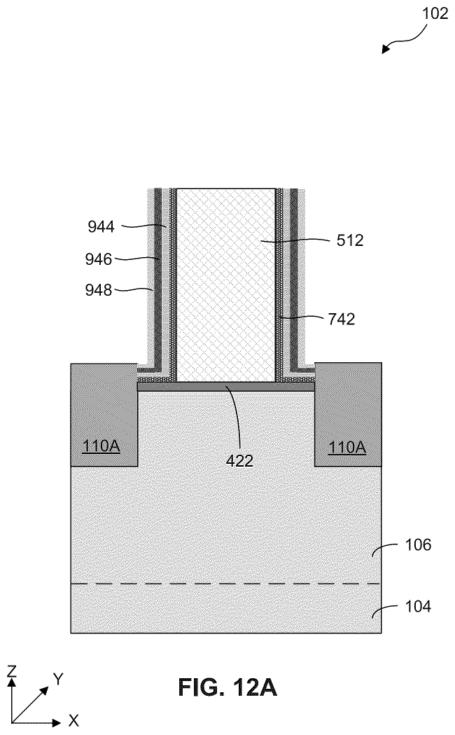

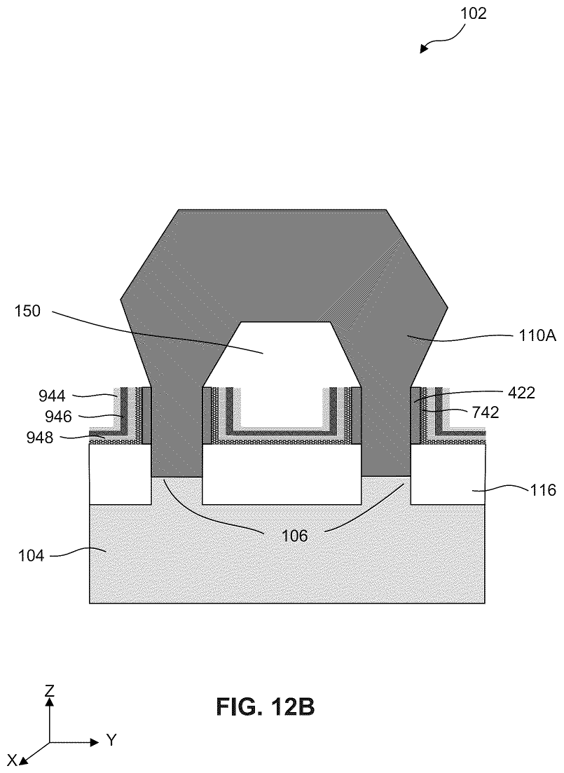

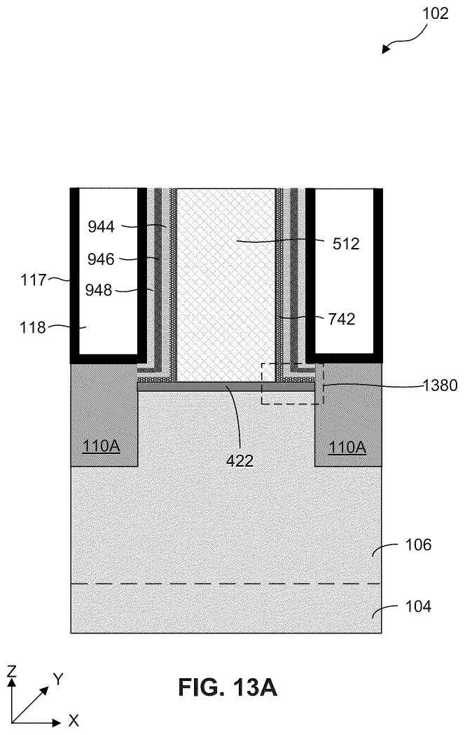

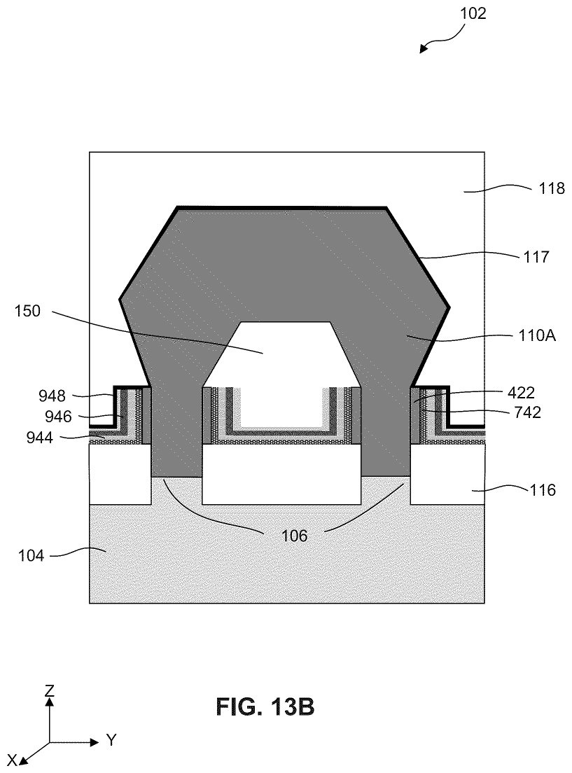

Referring to FIG. 2, in operation 230, S/D regions are formed on the fin structure and adjacent to the barrier layer. For example, as described with reference to FIGS. 10A-13B, S/D regions 110A are formed on fin structures 106. The formation of S/D regions 110A can include sequential operations of (i) removing portions of gate spacer layers 948, 946, and 944, barrier layer 742, and thermal oxide layer 422 to expose regions of fin structures 106, as shown in FIGS. 10A and 10B, (ii) forming S/D openings 1110 by removing portions of fin structures 106, portions of thermal oxide layer 422, portions of barrier layer 742, and portions of gate spacer layers 948, 946, and 944, as shown in FIGS. 11A and 11B, and (iii) epitaxially growing a semiconductor material in S/D openings 1110 to form S/D regions 110A in FIGS. 12A and 12B. After the formation of S/D regions 110A, ESL 117 and ILD layer 118 can be formed on S/D regions 110A, as shown in FIGS. 13A and 13B. In some embodiments, removing the portions of gate spacer layers 948, 946, and 944, barrier layer 742, and thermal oxide layer 422 can include patterning gate spacer layers 948 with a mask and etching the portions of gate spacer layers 948, 946, and 944, barrier layer 742, and thermal oxide layer 422 to expose regions of fin structure 106. In some embodiments, removing portions of fin structures 106 can include a dry etch, a wet etch, or a combination thereof. In some embodiments, epitaxially growing the semiconductor material in S/D openings 1110 can include (i) a CVD process, such as a low pressure CVD (LPCVD) process, a rapid thermal CVD (RTCVD) process, a metal-organic CVD (MOCVD) process, an atomic layer CVD (ALCVD) process, an ultrahigh vacuum CVD (UHVCVD) process, and a reduced pressure CVD (RPCVD) process; (ii) a molecular beam epitaxy (MBE) process; (iii) an epitaxial deposition/partial etch process, such as a cyclic deposition-etch (CDE) process; or (iv) a selective epitaxial growth (SEG) process. In some embodiments, forming S/D regions 110A can include epitaxially growing Ge, SiGe, or SiP in S/D openings 1110. In some embodiments, epitaxially growing the semiconductor material in S/D openings 1110 can include epitaxially growing the semiconductor material in adjacent S/D openings 1110 and forming merged S/D region 110A, as shown in FIG. 12B.

Referring to FIG. 2, in operation 235, an annealing process is performed to densify the gate spacer layers. For example, as described with reference to FIGS. 13A and 13B, gate spacer layers 948, 946, and 944 can be annealed at an annealing temperature. In some embodiments, the annealing temperature can be about 200° C. to about 1300° C. For example, the annealing temperature can be about 1200° C. to about 1250° C. In some embodiments, the annealing process can remove contaminants in gate spacer layers 944, 946, and 948. In some embodiments, the annealing process can improve atomic alignment of atoms in gate spacer layers 944, 946, and 948 to remove crystallographic defects, such as vacancies and dislocations. In some embodiments, the annealing process can improve a quality of gate spacer layers 944, 946, and 948 as an isolation structure between polysilicon structure 512 and S/D regions 110A.

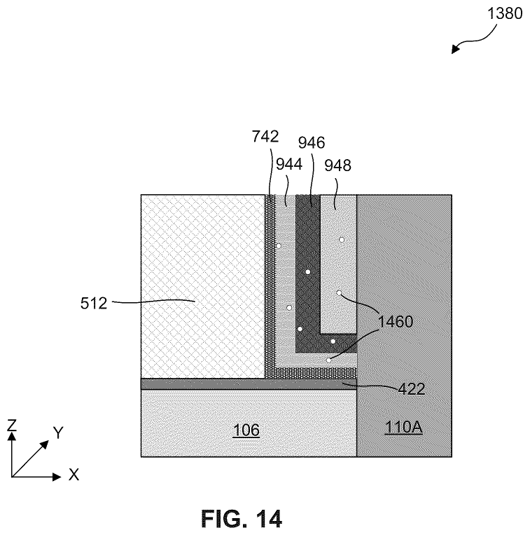

In some embodiments, due to the affinity between S/D regions 110A and gate spacer layers 944, 946, and 948, during the annealing process, atoms in S/D regions 110A can diffuse into gate spacer layers 944, 946, and 944, as shown in FIG. 14, which is an enlarged view of a region 1380 in FIG. 13A. For example, if S/D regions 110A include semiconductor materials such as Ge, during the annealing process, Ge atoms 1460 of S/D regions 110A can diffuse into gate spacer layers 944, 946, and 948.

If barrier layer 742 is not formed between polysilicon structure 512 and gate spacer layers 944, 946, and 948, Ge atoms 1460 of S/D regions 110A can diffuse through gate spacer layers 944, 946, and 948 into polysilicon structure 512. The diffused Ge atoms can then be removed by etching chemicals used in a subsequent operation 240 when polysilicon structure 512 is removed, thus introducing defects in gate spacer layers 944, 946, and 948. The defects can create a current leakage path between S/D regions 110A and subsequently-formed gate structures 112. However, the presence of barrier layer 742 can prevent the formation of such current leakage paths, as described with reference to FIG. 14.

The presence of barrier layer 742 can prevent Ge atoms 1460 from diffusing into barrier layer 742 and as a result, prevent Ge atoms 1460 from being removed in the subsequent operation 240 when polysilicon structure 512 is removed. Thus, the presence of barrier layer 742 can improve the performance of gate spacer layers 944, 946, and 948 as an isolation structure between S/D regions 110A and the subsequently-formed gate structure 112.

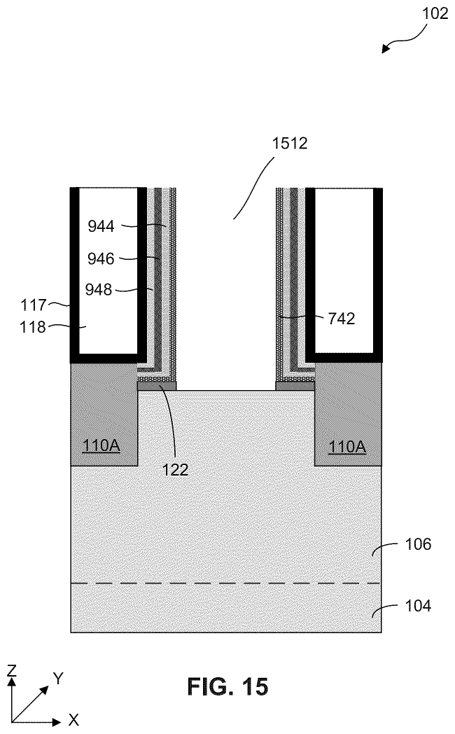

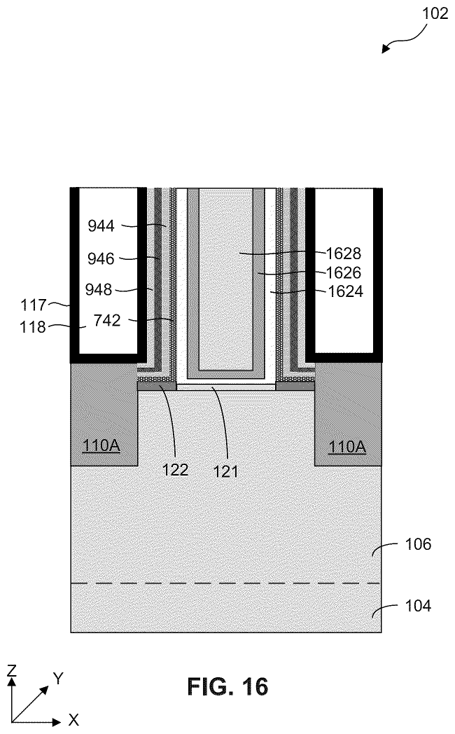

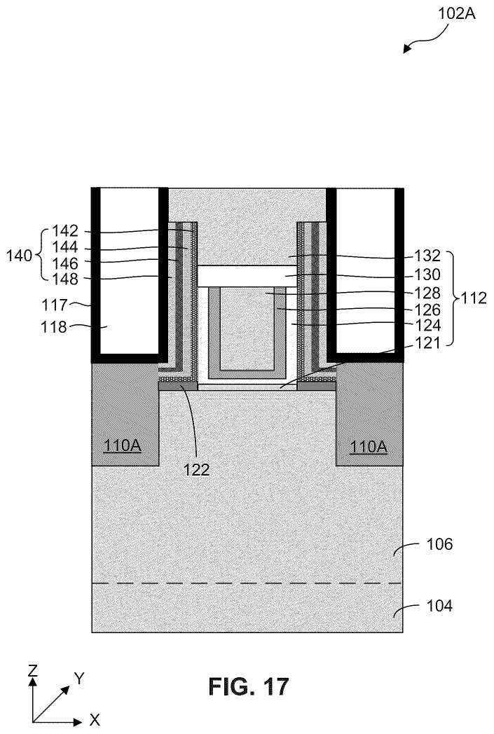

Referring to FIG. 2, in operation 240, the polysilicon structure is replaced with a gate structure adjacent to the barrier layer. For example, as described with reference to FIGS. 15-17, polysilicon structure 512 is replaced with gate structure 112. The replacement of polysilicon structure 512 with gate structure 112 can include sequential operations of (i) forming gate openings 1512 by removing polysilicon structure 512, (ii) removing an exposed portion of thermal oxide layer 422 in gate opening 1512 to expose a portion of fin structure 106, as shown in FIG. 15, (iii) forming an interfacial oxide layer 121 on the exposed portion of fin structure 106, (vi) depositing a HK gate dielectric layer 1624 on interfacial oxide layer 121 and sidewalls of barrier layer 742, (v) depositing a WFM layer 1626 on HK gate dielectric layer 1624, (vi) depositing a gate metal fill layer 1628 on WFM layer 1626, (vii) performing a chemical mechanical polishing (CMP) process on HK gate dielectric layer 1624, WFM layer 1626, and gate metal fill layer 1628 to form the structure of FIG. 16, (viii) etching HK gate dielectric layer 1624, WFM layer 1626, and gate metal fill layer 1628 to form HK gate dielectric layer 124, WFM layer 126, and a gate metal fill layer 128, as shown in FIG. 17, (ix) etching gate spacers layers 944, 946, and 948, and barrier layer 742 to form gate spacer 114 including gate spacers layers 144, 146, and 148, and barrier layer 142, as shown in FIG. 17, (x) forming a conductive capping layer 130 between a pair of barrier layers 142 and on HK gate dielectric layer 124, WFM layer 126, and gate metal fill layer 128, as shown in FIG. 17, and (xi) forming an insulating capping layer 132 on conductive capping layer 130, as shown in FIG. 17.

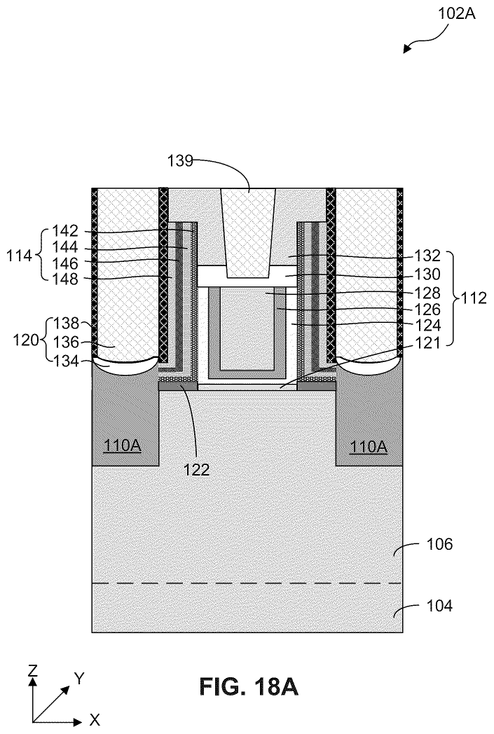

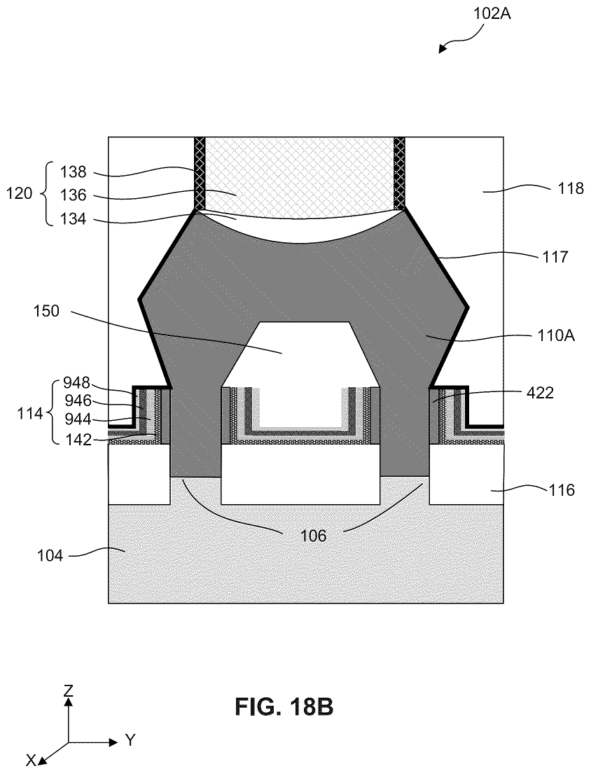

Referring to FIG. 2, in operation 245, contact structures are formed on the S/D regions and on the gate structure. For example, as described with reference to FIGS. 18A and 18B, S/D contact structures 120 are formed on S/D regions 110A, and gate contact structure 139 is formed on gate structure 112. In some embodiments, forming S/D contact structures 120 can include i) removing portions of ESL 117 and ILD layer 118 to expose S/D regions 110A, ii) forming silicide layers 134 on S/D regions 110A, iii) forming contact plugs 136 on silicide layers 134, and iv) forming nitride barrier layers 138 along sidewalls of contact plugs 136. In some embodiments, forming gate contact structures 120 can include forming an opening through insulating capping layer 132 and into conductive capping layer 130 and ii) filling the opening with a conductive material to form gate contact structure 139, as shown in FIGS. 18A and 18B.

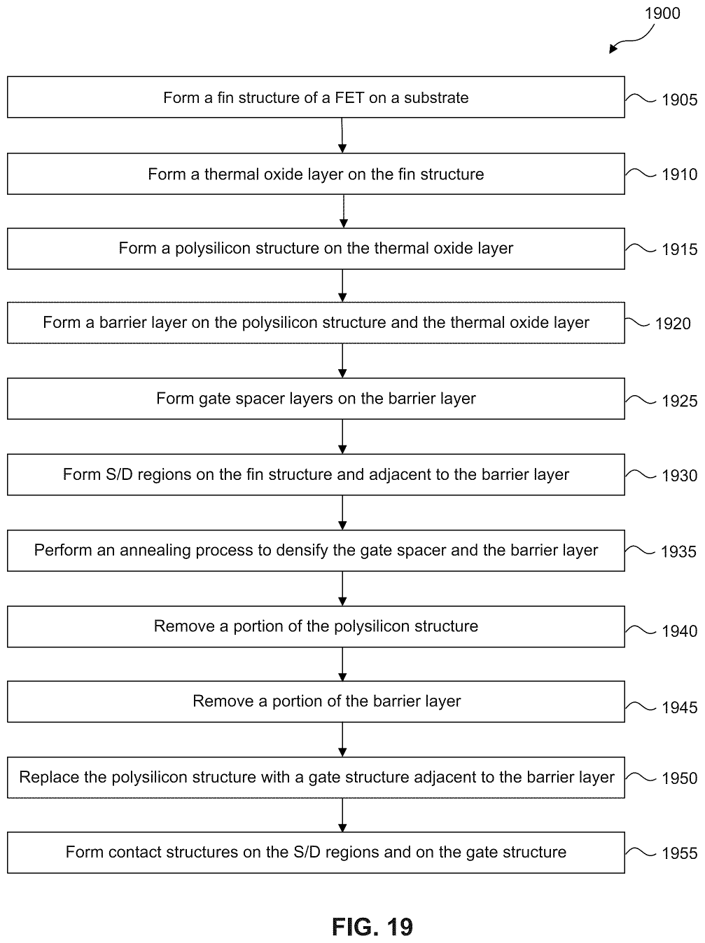

FIG. 19 is a flow diagram of an example method 1900 for fabricating FET 102B with cross-sectional views shown in FIG. 1F, according to some embodiments. For illustrative purposes, the operations illustrated in FIG. 19 will be described with reference to the example fabrication process for fabricating FET 102B as illustrated in FIGS. 3-5, 6A-13B, 14, and 20-24. FIGS. 3-5 are isometric views, FIGS. 6A, 7A, 8A, 8B, 9A, 10A, 11A, 12A, 13A, 14, and 20-24 are cross-sectional views of FET 102 along line A-A of FIG. 1A, and FIGS. 6B, 7B, 9B, 10B, 11B, 12B, and 13B are cross-sectional views of FET 102 along line B-B of FIG. 1A at various stages of fabrication, according to some embodiments. Operations can be performed in a different order or not performed depending on specific applications. It should be noted that method 1900 may not produce a complete FET 102B. Accordingly, it is understood that additional processes can be provided before, during, and after method 1900, and that some other processes may only be briefly described herein. Elements in FIGS. 3-5, 6A-13B, 14, and 20-24 with the same annotations as elements in FIGS. 1A-IF are described above.

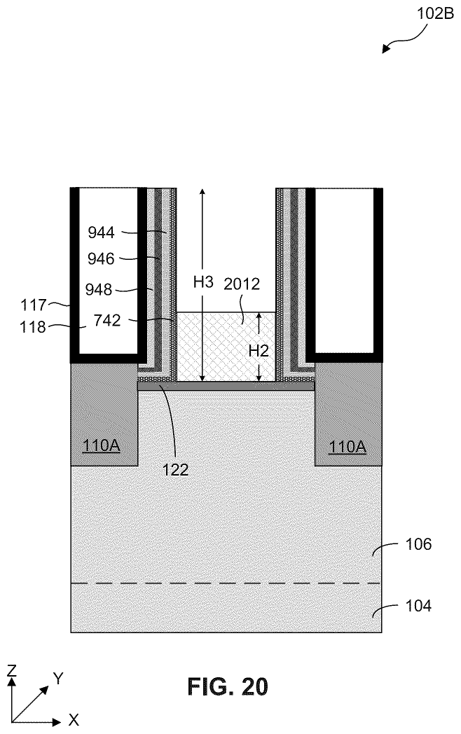

Referring to FIG. 19, operations 1905-1935 are identical or similar to operations 205-235 of FIG. 2. The discussion of operations 205-235 of method 200 applies to operations 1905-1935 of method 1900, unless mentioned otherwise. For this reason, the description of method 1900 will continue from operation 1940. The subsequent processing on the structures of FIGS. 13A, 13B, and 14 in operations 1940-1955 is described with reference to FIGS. 20-24.

Referring to FIG. 19, in operation 1940, a portion of the polysilicon structure is removed. For example, as described with reference to FIG. 20, polysilicon structure 512 of FIG. 13A is partially removed to form a polysilicon structure 2012 with a reduced height. In some embodiments, a height H2 of polysilicon structure 2012 can be reduced from a height H3 of polysilicon structure 512, such that height H2 is about 30% to about 50% of height H3. In some embodiments, partially removing polysilicon structure 512 can include etching polysilicon structure 512 while controlling the time of etching so that height H2 can be controlled.

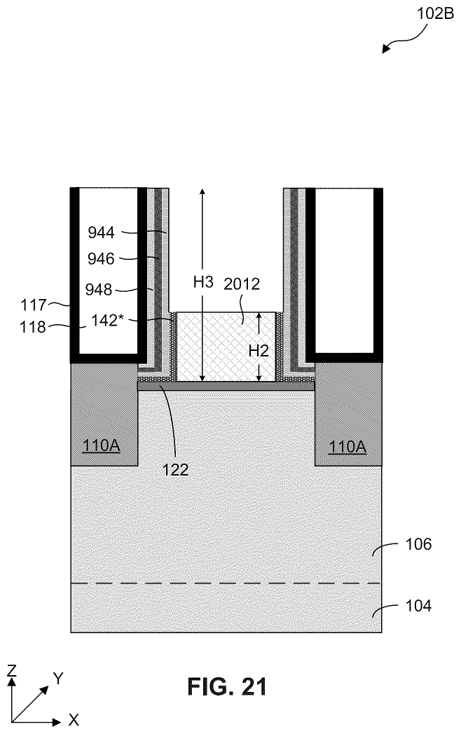

Referring to FIG. 19, in operation 1945, a portion of the barrier layer is removed. For example, as described with reference to FIG. 21, barrier layer 742 can be partially removed, such that the remaining portion of barrier layer 742 forms barrier layer 142*. In some embodiments, a height of barrier layer 742 can be substantially equal to height H3 of polysilicon structure 512. In some embodiments, reducing height H3 of barrier layer 742 to height H2 can include etching portions of barrier layer 742 that are not covered by polysilicon structure 2012. In some embodiments, polysilicon structure 2012 can be used as a masking structure to control the portions of barrier layer 742 to be etched and subsequently, control height H2 of barrier layer 142*. In some embodiments, reducing height H3 of barrier layer 742 can include a dry etch, a wet etch, or a combination thereof. In some embodiments, reducing height H3 of barrier layer 742 can include forming a patterned mask on top surfaces of gate spacer layers 944, 946, and 948 to prevent them from being etched during the etching of barrier layer 742. In some embodiments, reducing height H3 of barrier layer 742 can provide larger areas for the formation of electrical contact on gate structure 112 formed in subsequent operation 1950.

In some embodiments, reducing height H3 of barrier layer 742 can be performed in approaches different from that described with reference to FIGS. 20 and 21. For example, height H3 of barrier layer 742 can be reduced by i) completely removing polysilicon structure 512 (as described in FIG. 15), ii) using a patterned mask to cover top surfaces of gate spacer layers 944, 946, and 948, iii) etching barrier layer 742 while controlling the time of etching until height H3 of barrier layer 742 is reduced to height H2 of barrier layer 142*.

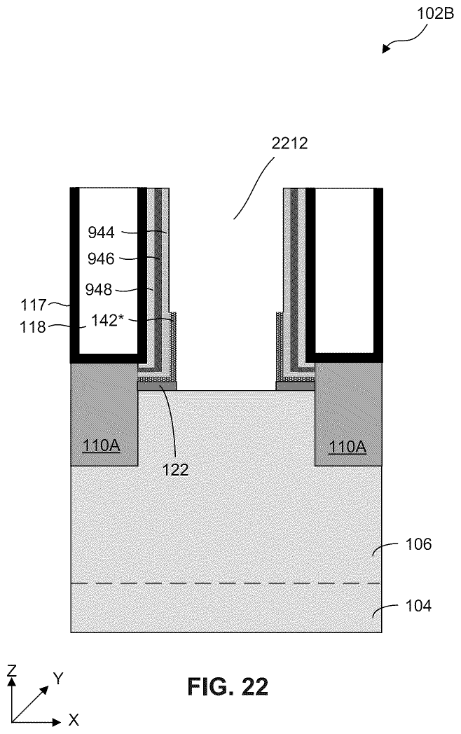

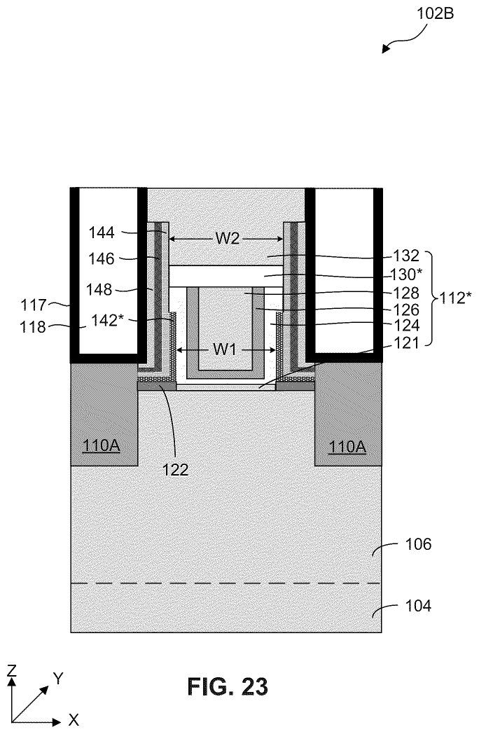

Referring to FIG. 19, in operation 1950, the polysilicon structure is replaced with a gate structure adjacent to the barrier layer. Operation 1950 is similar to operation 240 of FIG. 2. For example, as described with reference to FIGS. 22 and 23, polysilicon structure 2012 is replaced with gate structure 112*. The replacement of polysilicon structure 512 with gate structure 112* can include sequential operations of (i) forming gate openings 2212 by removing polysilicon structures 2012, (ii) removing an exposed portion of thermal oxide layer 422 in gate opening 2212 to expose a portion of fin structure 106, as shown in FIG. 22, (iii) forming an interfacial oxide layer 121 on the exposed portion of fin structure 106, as shown in FIG. 23, (vi) forming HK gate dielectric layer 124 on interfacial oxide layer 121 and sidewalls and top surfaces of barrier layers 142*, as shown in FIG. 23, (v) forming WFM layer 126 on HK gate dielectric layer 124, as shown in FIG. 23, (vi) forming gate metal fill layer 128 on WFM layer 126, as shown in FIG. 23, (vii) etching gate spacers layers 944, 946, and 948 to form a gate spacer 114* including gate spacers layers 144, 146, and 148, and barrier layer 142*, as shown in FIG. 23, (viii) forming conductive capping layer 130* between a pair of barrier layers 142* and on HK gate dielectric layer 124, WFM layer 126, and gate metal fill layer 128, as shown in FIG. 17, and (ix) forming insulating capping layer 132 on conductive capping layer 130, as shown in FIG. 23.

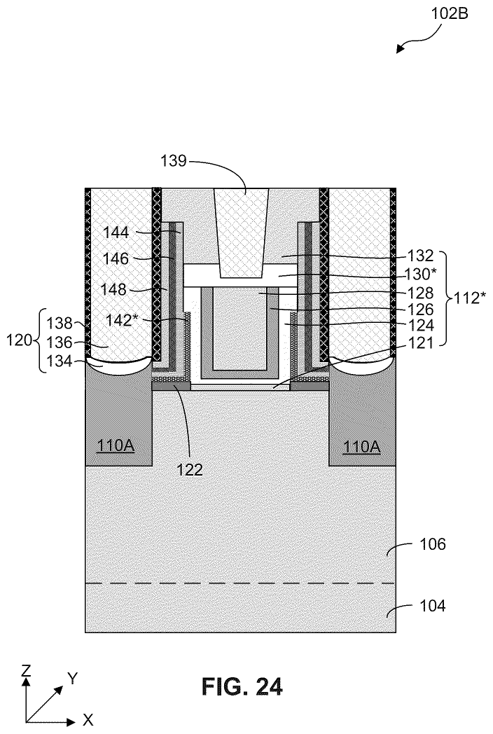

Referring to FIG. 19, in operation 1955, contact structures are formed on the S/D regions and on the gate structure. Operation 1955 is similar to operation 245 of FIG. 2. For example, as shown in FIG. 24, S/D contact structures 120 are formed on S/D regions 110A, and gate contact structure 139 is formed on gate structure 112*. In some embodiments, forming S/D contact structures 120 can include i) removing portions of ESL 117 and ILD layer 118 to expose S/D regions 110A, ii) forming silicide layers 134 on S/D regions 110A, iii) forming contact plugs 136 on silicide layers 134, and iv) forming nitride barrier layers 138 along sidewalls of contact plugs 136. In some embodiments, forming gate contact structures 120 can include forming an opening through insulating capping layer 132 and into conductive capping layer 130 and ii) filling the opening with a conductive material to form gate contact structure 139, as shown in FIG. 24.

The present disclosure provides example structures of FETs (e.g., FETs 102A, 102B, and 102C) having a barrier layer (e. g., barrier layers 142 and 142*) between a gate structure and gate spacer layers to improve the performance of gate spacer layers as an isolator between S/D regions and the gate structure. The present disclosure also provides example methods (e.g., method 200 and 1900) of forming FETs that include the barrier layer by nitridation of a polysilicon structure. In some embodiments, the barrier layer can be a SiN layer and is hydrogen free. In some embodiments, the barrier layer can prevent atoms of the S/D regions diffusing into gate spacer layers from diffusing through the barrier layer during an annealing process to densify the gate spacer layers. In some embodiments, the barrier layer can prevent atoms diffusing into the gate spacer layers from being removed in a process of forming the gate structure. In some embodiments, the barrier layer can include a vertical portion on a side surface of the gate structure and include a horizontal portion on a surface of thermal oxide layer on a fin structure. In some embodiments, the vertical and horizontal portions of the barrier layer (e. g., barrier layers 142₁) can have a substantially same thickness. In some embodiments, the vertical and horizontal portions of the barrier layer (e. g., barrier layers 142₂) can have different thicknesses. In some embodiments, the vertical portion can have a thickness greater than that of the horizontal portion. In some embodiments, the barrier layer can have a reduced height (e. g., barrier layer 142*), such that a conductive capping layer of the gate structure can have a greater width, which can reduce the resistivity of the conductive capping layer and improve the performance of the gate structure.

In some embodiments, a method includes forming a fin structure on a substrate, forming a polysilicon structure on the fin structure, performing a nitridation process to form a nitride layer on sidewalls of the polysilicon structure, forming a gate spacer on the nitride layer,, forming a source/drain region adjacent to the nitride layer and the polysilicon structure, performing an annealing process to densify the gate spacer, and replacing the polysilicon structure with a gate structure.

In some embodiments, a method includes forming a polysilicon structure on a substrate, performing a nitridation process to form a barrier layer on the polysilicon structure, forming a gate spacer on the barrier layer, forming a source/drain region adjacent to the barrier layer, performing an annealing process to densify the gate spacer, adjusting a height of the barrier layer, and replacing the polysilicon structure with a gate structure.

In some embodiments, a semiconductor device includes a substrate, a fin structure on the substrate, a gate structure disposed on the fin structure, a hydrogen-free nitride layer disposed on the fin structure and sidewalls of the gate structure, a gate spacer layer disposed on the hydrogen-free nitride layer, and a source/drain region disposed on the fin structure and adjacent to the hydrogen-free nitride layer.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a fin structure on a substrate;
forming a polysilicon structure on the fin structure;
performing a nitridation process to form a nitride layer on sidewalls of the polysilicon structure;
forming a gate spacer on the nitride layer;
forming a source/drain region adjacent to the nitride layer and the polysilicon structure;
performing an annealing process to densify the gate spacer; and
replacing the polysilicon structure with a gate structure.

2. The method of claim 1, wherein performing the nitridation process comprises exposing the polysilicon structure to a nitrogen plasma.

3. The method of claim 1, wherein performing the nitridation process comprises controlling parameters of the nitridation process to form the nitride layer with a thickness of about 2 Å to about 5 Å.

4. The method of claim 1, wherein performing the nitridation process comprises exposing the polysilicon structure to a nitrogen plasma for a duration of about 1 sec to about 5 sec.

5. The method of claim 1, wherein performing the nitridation process comprises forming a hydrogen-free silicon nitride layer on the sidewalls of the polysilicon structure.

6. The method of claim 1, further comprising forming a thermal oxide layer on the fin structure, wherein performing the nitridation process comprises forming a portion of the nitride layer on a surface of the thermal oxide layer.

7. The method of claim 1, wherein performing the nitridation process comprises forming a horizontal portion of the nitride layer with a first thickness and a vertical portion of the nitride layer with a second thickness greater than the first thickness.

8. The method of claim 1, wherein replacing the polysilicon structure with the gate structure comprises forming a high-k gate dielectric layer of the gate structure on a top surface and a sidewall of the nitride layer.

9. A method, comprising:
forming a polysilicon structure on a substrate;
performing a nitridation process to form a barrier layer on the polysilicon structure;
forming a gate spacer on the barrier layer;
forming a source/drain region adjacent to the barrier layer;
performing an annealing process to densify the gate spacer;
adjusting a height of the barrier layer; and
replacing the polysilicon structure with a gate structure.

10. The method of claim 9, wherein performing the nitridation process comprises exposing the polysilicon structure to a nitrogen plasma.

11. The method of claim 9, wherein performing the nitridation process comprises forming the barrier layer with a thickness of about 2 Å to about 5 Å.

12. The method of claim 9, wherein performing the nitridation process comprises exposing the polysilicon structure to a nitrogen plasma for a duration of about 1 sec to about 5 sec.

13. The method of claim 9, wherein performing the nitridation process comprises forming a hydrogen-free silicon nitride layer on the polysilicon structure.

14. The method of claim 9, wherein adjusting the height of the barrier layer comprises:
removing an upper portion of the polysilicon structure;
etching the barrier layer using a lower portion of the polysilicon structure as a masking layer.

15. The method of claim 9, wherein performing the nitridation process comprises forming a horizontal portion of the barrier layer with a first thickness and a vertical portion of the barrier layer with a second thickness greater than the first thickness.

16. The method of claim 9, wherein performing the nitridation process comprises forming the barrier layer with an L-shaped cross-sectional profile.

17. A device, comprising:
a substrate;
a fin structure disposed on the substrate;
a gate structure disposed on the fin structure;
a hydrogen free nitride layer disposed on the fin structure and sidewalls of the gate structure;
a gate spacer layer on the hydrogen free nitride layer; and
a source/drain region disposed on the fin structure and adjacent to the hydrogen free nitride layer.

18. The device of claim 17, wherein the hydrogen free nitride layer comprises a vertical portion on sidewalls of the gate structure and horizontal a portion on the fin structure, and wherein a thickness of the vertical portion is greater than a thickness of the horizontal portion by at least 10%.

19. The device of claim 17, wherein a height of the hydrogen free nitride layer is substantially the same as a height of the gate spacer.

20. The device of claim 17, wherein a ratio between a height of the hydrogen free nitride layer and a height of the gate spacer layer is between about 30% and about 50%.
